(19) United States
(12) Patent Application Publication
(10) Pub. No.: US 2026/0096364 A1
(43) Pub. Date: Apr. 2, 2026

(54) LOW-TEMPERATURE ETCHING OF CARBON-CONTAINING LAYERS

(71) Applicant: Tokyo Electron Limited, Tokyo (JP)

(72) Inventors: Shihsheng Chang, Albany, NY (US); Du Zhang, Albany, NY (US); Yen-Tien Lu, Albany, NY (US)

(21) Appl. No.: 18/899,263

(22) Filed: Sep. 27, 2024

(51) Int. Cl. H01L 21/3065; H01L 21/308

(52) U.S. Cl. CPC H10P 50/242; H10P 50/691

(57) ABSTRACT

A method for etching a layer includes loading a substrate onto a substrate holder disposed within a processing chamber, the substrate including a carbon-containing layer and a patterned mask layer; cooling the substrate holder to a first temperature between −150° C. and −40° C.; and while maintaining the first temperature of the substrate holder, patterning the carbon-containing layer to form a channel in the carbon-containing layer, the patterning including simultaneously flowing into the processing chamber an etching gas including oxygen and a passivating gas including silicon and fluorine; and generating a plasma within the processing chamber.

### TECHNICAL FIELD

The present invention relates generally to methods of processing a substrate, and, in particular embodiments, to low-temperature etching of carbon-containing layers.

### BACKGROUND

As the physical pitch associated with technology nodes in production has shrunk from hundreds to tens of nanometers, the challenge of increasing device densities has been compounded by physical limits on device reliability and performance. Planar NAND devices reached these limits with the advent of 193-nm immersion lithography, for example, spurring the development of 3D NAND memory architectures incorporating dozens (or even hundreds) of stacked word plates.

Forming a contact to any given word plate in a 3D NAND memory entails etching a narrow channel from the top of the stack-through any intervening interlayer dielectric material-to reach a corresponding gate electrode. A majority of the contact channels in a modern, highly vertical memory device will have a depth:width ratio of 20:1 or higher and may be called high-aspect ratio (HAR) features.

Conventional photoresists applied in the requisite thicknesses to pattern HAR features in a substrate may absorb unevenly, yielding blurred patterns; may be mechanically unstable or even collapse; and may not exhibit sufficient resistance to anisotropic etching methods over lengthy exposures. As a result, HAR features are often formed by depositing, patterning, and etching one or more durable hard masks that may then be used to transfer a pattern to the substrate.

### SUMMARY

In an embodiment, a method for etching a layer includes loading a substrate onto a substrate holder disposed within a processing chamber, the substrate including a carbon-containing layer and a patterned mask layer; cooling the substrate holder to a first temperature between −150° C. and −40° C.; and while maintaining the first temperature of the substrate holder, patterning the carbon-containing layer to form a channel in the carbon-containing layer, the patterning including simultaneously flowing into the processing chamber an etching gas including oxygen and a passivating gas including silicon and fluorine; and generating a plasma within the processing chamber.

In another embodiment, a method for etching a layer includes loading a substrate onto a substrate holder disposed within a processing chamber, the substrate including an amorphous carbon layer and a patterned mask layer; cooling the substrate holder to a first temperature between −100° C. and −40° C.; and while maintaining the first temperature of the substrate holder, patterning the amorphous carbon layer to form a channel in the amorphous carbon layer, the patterning including simultaneously flowing into the processing chamber an etching gas including oxygen, a passivating gas including a fluorinated silane, and a sulfur-containing gas; and generating a plasma within the processing chamber.

In still another embodiment, a method for etching a layer includes loading a substrate onto a substrate holder disposed within a processing chamber, the substrate being thermally coupled to the substrate holder, the substrate including a carbon-containing layer and a patterned mask layer; over a first time period, cooling the substrate holder to a first temperature between-150° C. and −40° C.; while maintaining the first temperature of the substrate holder, stabilizing the substrate at a second temperature over a second time period; and after the second time period, exposing the substrate to a plasma over a third time period, the plasma being generated from a gas mixture including an etching gas and a passivating gas, the etching gas including oxygen, the passivating gas including silicon and fluorine.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1C illustrate cross-sectional views of the etching of HAR channels in a carbon-containing layer of a substrate with a pattern defined by a patterned mask layer, followed by low-temperature etching of an underlying material layer, in accordance with various embodiments, wherein FIG. 1A illustrates an incoming substrate comprising a patterned mask layer, an underlying material layer, and a bottom layer, FIG. 1B illustrates the substrate after low-temperature etching of the carbon-containing layer and formation of HAR channels according to embodiments, and FIG. 1C illustrates the substrate after a subsequent etch of the underlying material layer;

FIGS. 2A and 2B illustrate cross-sectional schematic views of etching apparatus using (respectively) inductively coupled plasma and capacitively coupled plasma to etch a substrate disposed over a cooled substrate holder, in accordance with various embodiments;

FIGS. 3A-3C provide flow charts for methods of etching a layer, and in particular for etching a carbon-containing layer of a substrate with process gases comprising an etching gas and a passivating gas, and while maintaining a first temperature of a substrate holder, according to various embodiments, wherein FIG. 3A charts a method comprising a first temperature between −150° C. and −40° C., FIG. 3B charts a method comprising a first temperature between −100° C. and −40° C. and etching with process gases further comprising a sulfur-containing gas, and FIG. 3C charts a method further comprising cooling time protocols;

FIGS. 4A and 4B provide a cross-sectional comparison between (respectively) channels formed by a hypothetical wholly anisotropic etching process and bowed channels formed in practice by anisotropic etching, according to embodiments;

FIGS. 5A-5C provide a cross-sectional comparison between different modes of deposition of an additional mask material layer over a patterned mask layer that may occur during an etching process, and in particular between (respectively) roughening, clogging, and blanketing, according to embodiments; and

FIGS. 6A-6D provide corresponding top-down views of a portion of an etched substrate, wherein FIG. 6A complements FIG. 4A and FIGS. 6B-6D respectively complement FIGS. 5A-5C, according to various embodiments.

### DETAILED DESCRIPTION OF ILLUSTRATIVE EMBODIMENTS

Fabrication of three-dimensional memory devices such as 3D NAND, 3D NOR, and dynamic random access memory (DRAM) may generally require forming HAR features, such as memory channels or contact holes. Features with depth:width aspect ratios of 20:1 are increasingly common in advanced logics (such as fin field-effect transistors, FinFETs) and integration structures (such as through-silicon vias), with aspect ratios of 50:1, 100:1, and higher appearing in advanced memory designs.

In memory devices, HAR features may be formed in a dielectric material (such as silicon oxide, silicon nitride, silicon oxynitride, or a stack of alternating silicon oxide and silicon nitride layers) with high fidelity using anisotropic plasma etching. Because conventional photoresists are not generally sufficiently durable to withstand exposure to plasma for the minutes or hours that may be required to form HAR features, a desired patterning may be achieved by depositing a durable hard-mask material (such as amorphous carbon) over the dielectric and etching it with the pattern to be transferred, then further etching the underlying material layer.

High-fidelity, highly anisotropic etch methods with high etch rates and smooth feature profiles may be achieved using oxygen (O₂) plasma etchant in combination with passivating gases that serve to protect sidewalls of a channel from lateral etching. Among other possible chemistries, and according to various embodiments, these passivating gases may comprise silicon and a halogen (such as fluorine), or a sulfur-containing gas, or a hydrogen-containing gas, or combinations thereof. Passivation of the channel sidewalls may prevent or mitigate undesirable outcomes like undercutting (compromising the anisotropy of the etch) or variations in the feature profile (such as bowing) that exceed tolerances.

Anisotropic etch chemistries in common use for patterning carbon-containing layers with HAR features have certain shortcomings. For example, oxygen/tetrachlorosilane (O₂/SiCl₄) etches exhibit a relatively narrow process window, may produce defects in a pattern by leaving excessive amounts of residue on the etched surface, and may clog channels to the point of changing the effective critical dimension (or even causing etch stop). As another example, oxygen/sulfur dioxide (O₂/SO₂) etches may not provide adequate protection to the channel sidewalls, and they may result in the formation of sulfuric acid (H₂SO₄) or other sulfur-containing oxyacids. Acid contamination may damage semiconductor workpieces or the etching equipment and may entail additional abatement measures such as scrubbers. Consequently, modified etch chemistries that improve on conventional chemistries are desired.

Embodiments of this application describe a complementary strategy for process improvement that includes modifying the conditions under which the etching is performed. In various embodiments, the semiconductor workpiece is cooled below freezing (or even to cryogenic temperatures) during etching, potentially allowing the controlled use of etch chemistries that are too aggressive at room temperature. Irrespective of any particular choice of chemistry, etching methods comprising a cooled substrate may have additional salutary features, such as improved sidewall passivation and reductions in residue and the risk of clogging. Embodiments described herein therefore enable the formation of HAR features with improved characteristics for advanced logic, integration, and memory applications.

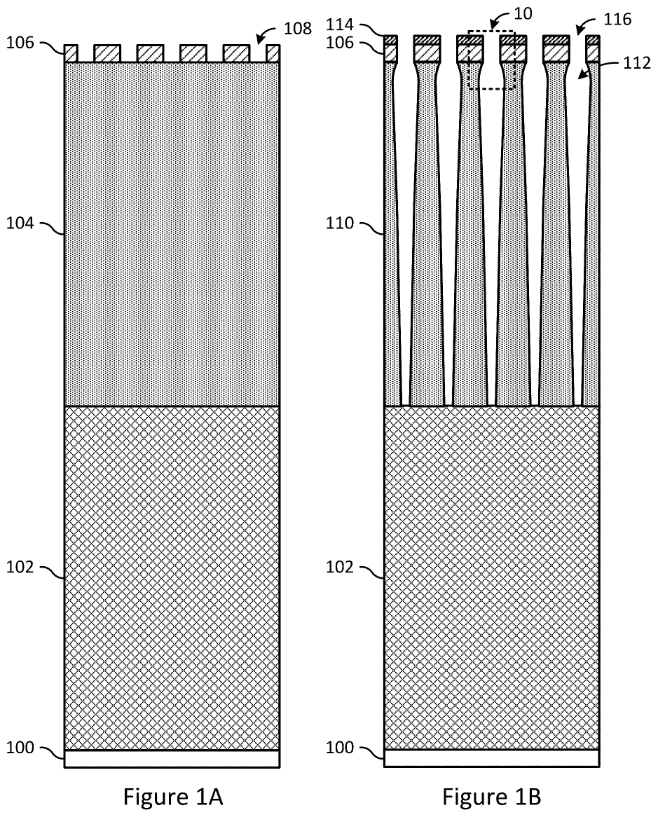

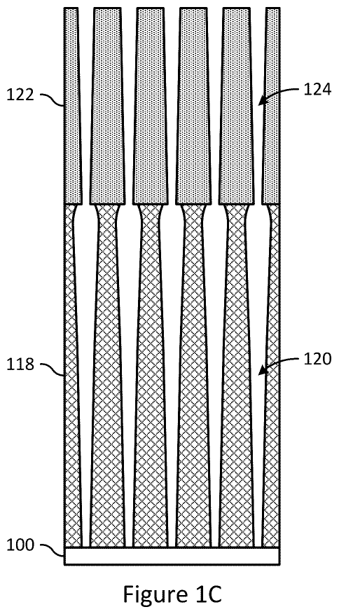

FIGS. 1A-1C illustrate cross-sectional views of the low-temperature etching of HAR channels in a carbon-containing layer of a substrate with a pattern defined by a patterned mask layer, followed by etching of an underlying material layer, in accordance with various embodiments. In particular, FIG. 1A illustrates an incoming semiconductor workpiece (or substrate) comprising a bottom layer 100, an underlying material layer 102, a carbon-containing layer 104, and a patterned mask layer 106. The patterned mask layer 106 comprises mask channels 108 that define the positions and critical dimension (CD) of channels to be etched in the carbon-containing layer 104.

The bottom layer 100 represents generically any suitable semiconductor substrate being processed in accordance with embodiments of the present invention. The bottom layer 100 may be a bulk substrate such as a silicon wafer, a silicon-on-insulator (SOI) wafer, or any of various other semiconductor substrates. The bottom layer 100 may also be coated or layered with any number of additional materials, including compound semiconductors, metal or metalloid oxides, or metal or metalloid nitrides.

The bottom layer 100 may include any material portion or structure of a device, particularly a semiconductor or other electronics device. Similarly, in some embodiments, the bottom layer 100 may itself be patterned or embedded in other components of a semiconductor structure or device, such as a reconstituted wafer in a wafer-level package process. In some such embodiments, the bottom layer 100 may include various device regions and isolation regions (such as shallow trench isolation regions), as well as other regions formed therein.

The underlying material layer 102 is disposed over the bottom layer 100. In various embodiments, the underlying material layer 102 is a target layer to be patterned by a plasma etch process subsequent to patterning and low-temperature etching of the carbon-containing layer 104. In certain embodiments, a feature being etched into the underlying material layer 102 may be a memory channel, a contact hole, a slit, or another desired structure.

In various embodiments, the underlying material layer 102 may comprise a dielectric material. In certain such embodiments, the underlying material layer 102 may comprise silicon oxide. In other such embodiments, the underlying material layer 102 may comprise silicon nitride, silicon oxynitride, or a stack of alternating layers of silicon oxide and silicon nitride. The underlying material layer 102 may be deposited using any suitable deposition technique, such as physical vapor deposition (PVD) by sputtering, evaporation, or molecular beam evaporation; pulsed laser deposition (PLD); atomic layer deposition (ALD); chemical vapor deposition (CVD); plasma-enhanced CVD or ALD; metal-organic CVD; low-pressure CVD; rapid thermal CVD; or any other layer-deposition process or combination thereof. In an embodiment, the underlying material layer 102 may have a thickness between 0.5 μm and 12 μm.

With further reference to FIG. 1A, the carbon-containing layer 104 is disposed over the underlying material layer 102. In various embodiments, the carbon-containing layer 104 may be an amorphous carbon layer, providing advantageous hard mask features such as high etch selectivity and resistance to a variety of etch chemistries. In some such embodiments, the carbon-containing layer 104 may comprise a soft (graphitizable) amorphous carbon or a hard (non-graphitizable) amorphous carbon.

In some embodiments, the carbon-containing layer 104 may be fully amorphous, while in other embodiments the degree of crystallinity may vary up to 100%. In some embodiments, the carbon-containing layer 104 may further comprise various additives such as hydrogen, boron, nitrogen, oxygen, and phosphorus. The carbon-containing layer 104 may be deposited using, for example, an appropriate spin-coating technique or any suitable layer-deposition process or combination thereof described above. In embodiments, the carbon-containing layer 104 may be an advanced patterning film deposited using plasma-enhanced CVD.

In various embodiments, the carbon-containing layer 104 may be the layer to be patterned in preparation for the formation (by a subsequent etching process) of HAR features in the underlying material layer 102. The thickness of the carbon-containing layer 104 may vary, depending (for example) on the selectivity of the subsequent etching process or on the desired aspect ratio of HAR features in the underlying material layer 102. The carbon-containing layer 104 may therefore be thicker than, thinner than, or the same thickness as the underlying material layer 102, according to various embodiments. In some embodiments, the carbon-containing layer 104 may have a thickness between 0.1 μm and 5 μm.

With further reference to FIG. 1A, the patterned mask layer 106 is disposed over the carbon-containing layer 104. The patterned mask layer 106 may comprise any suitable mask material. In some embodiments, the patterned mask layer 106 may comprise a dielectric material, such as silicon oxide or silicon oxynitride. In other embodiments, the patterned mask layer 106 may comprise a metal-based mask such as tungsten carbide or tungsten silicide.

According to various embodiments, the patterned mask layer 106 may be produced by depositing a mask layer using any of the layer deposition techniques described above, then using any suitable lithography technique in combination with an anisotropic etching method (such as reactive ion etching) to form the pattern. Lithography techniques used may comprise dry lithography (e.g., 193-nanometer dry lithography), immersion lithography (e.g., 193-nanometer immersion lithography), i-line lithography (e.g., using 365-nanometer wavelength UV radiation), H-line lithography (e.g., using 405-nanometer wavelength UV radiation), extreme UV (EUV) lithography, high numerical aperture EUV (high NA-EUV), or deep UV (DUV) lithography, according to various embodiments.

Although not illustrated in FIG. 1A, the substrate may comprise other layers during various stages of processing. For example, for the purpose of patterning the mask layer to form the patterned mask layer 106, a tri-layer structure comprising a photoresist layer, a silicon-based anti-reflective layer, and an optical planarization layer may be present.

FIG. 1B illustrates the substrate after the carbon-containing layer 104 has been etched at low temperature to form a patterned carbon-containing layer 110, according to various embodiments to be described in detail below. In various embodiments, low-temperature etching of the substrate may comprise loading the substrate onto a substrate holder within a plasma processing chamber. In some embodiments, the low-temperature etching may be performed in the same chamber as the processing chamber used in patterning the mask layer in FIG. 1A. The substrate holder may be cooled and maintained at a temperature between −150° C. and −40° C., either prior to loading the substrate onto the substrate holder or afterward. An etching gas comprising oxygen and a passivating gas comprising silicon and fluorine are simultaneously flowed into the plasma processing chamber. A plasma may be ignited and powered within the processing chamber as the etching gas and the passivating gas continue to flow. The substrate is thermally coupled to the substrate holder, e.g., physically contacting the substrate holder, causing conductive heat loss from the substrate to the substrate holder. As a result, the substrate may be maintained at steady state, after a suitable stabilization time, at a temperature between −150° C. and −40° C. In some embodiments the substrate holder may be maintained at a temperature between −100° C. and −40° C. accordingly cooling the substrate as such. In other embodiments, the substrate holder may be cooled to a temperature below −100° C., and the substrate may be under cryogenic conditions.

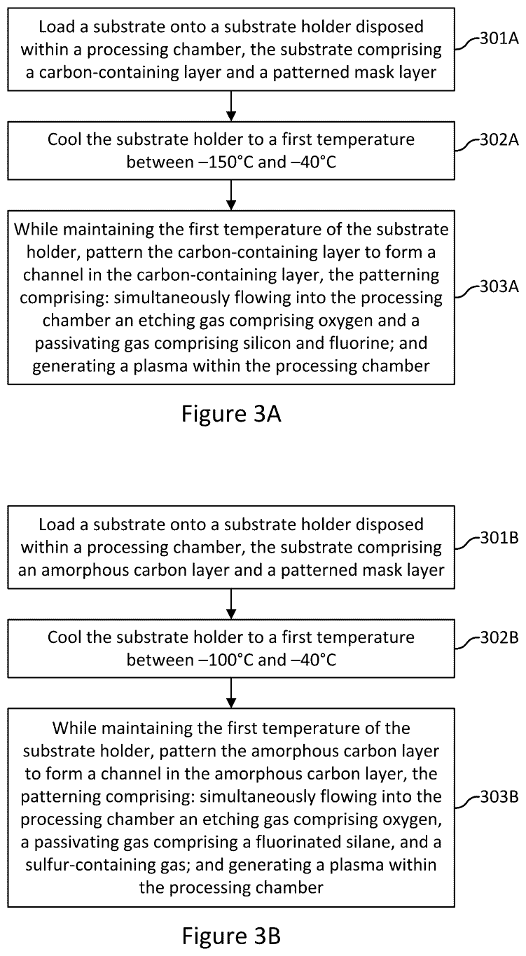

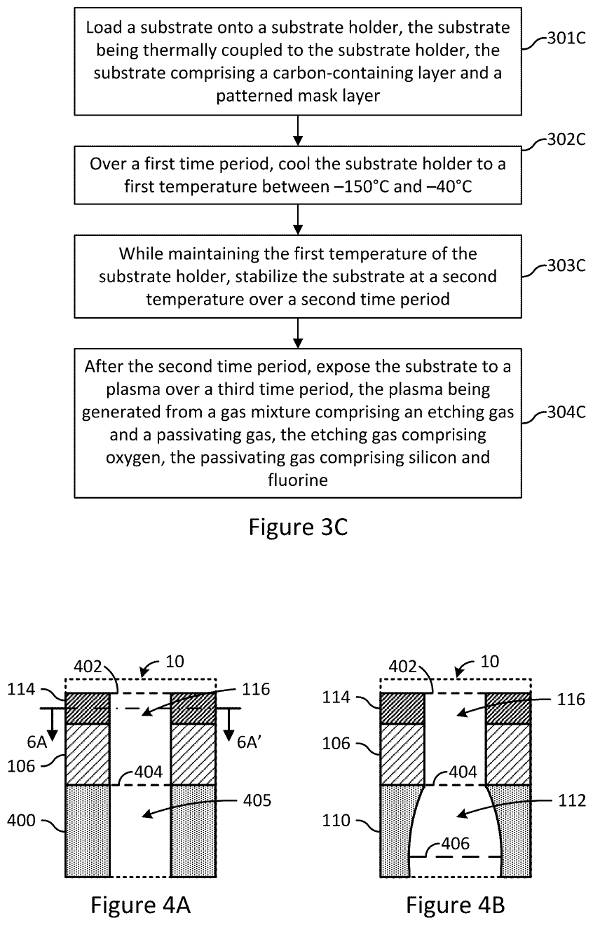

Advantageously, as described further in more detail below and also in the description of FIGS. 3A-3C, the use of lower temperature etching enables the use of etch chemistries that are too aggressive at room temperature. For example, embodiments may use a plasma generated from oxygen and fluorine-containing gases such as SiF₄ or SiHₙF₄₋ₙ (0≤n≤3) with the substrate cooled to low temperatures, e.g., below −100° C., to achieve a wider process window than possible with chlorine-based etching, such as with SiCl₄. Without committing to any particular mechanism, this wider achievable process window may be attributed to formation of a SiOₓF_{y} film that may provide sidewall protection at low temperatures and sublime after the substrate is warmed to room temperature, leaving minimal or no residue. In another example, embodiments may use a plasma generated from oxygen, a fluorine-containing gas such as SiF₄ or SiHₙF₄₋ₙ (0≤n≤3), and a sulfur-containing gas such as SO₂ with the substrate cooled to low temperatures, e.g., below −40° C., to achieve various improvements in the feature profile after the etching.

In some embodiments, the processing chamber may be part of an inductively coupled plasma (ICP) etching apparatus; in other embodiments, the processing chamber may be part of a capacitively coupled plasma (CCP) etching apparatus.

Irrespective of how a plasma may be generated within the processing chamber, exposing the substrate to the plasma for at least 5 minutes may form HAR channels 112 in the patterned carbon-containing layer 110 with aspect ratio of at least 20:1, according to various embodiments. In general, the higher the target aspect ratio, the longer the etch time may be. In some embodiments, forming the patterned carbon-containing layer 110 may comprise an etch time of 30 minutes or longer.

In addition to forming HAR channels 112 in the patterned carbon-containing layer 110, the low-temperature etching may also (in some embodiments) deposit a mask material layer 114 over the patterned mask layer 106, forming deeper mask channels 116 and advantageously providing more robust masking for the subsequent etch of the underlying material layer 102. (Some conventional methods for etching carbon-containing layers may deposit little or no additional mask material.) In various embodiments, the mask material layer 114 may have a thickness between 10% and 75% of an initial thickness of the patterned mask layer.

HAR channels 112 may extend downward from an upper surface of the patterned carbon-containing layer 110, stopping at an interface with the underlying material layer 102 (in some embodiments) because the low-temperature etching process may be selective to the underlying material layer 102.

HAR channels 112 may comprise any shapes and structures useful for semiconductor device fabrication, such as a contact hole, a slit, or other suitable structure. In various embodiments, a HAR channel 112 has a depth:width aspect ratio of 20:1 or greater. In certain embodiments, the aspect ratio may be between 40:1 and 200:1. A critical dimension of a HAR channel 112 at its upper opening—a top critical dimension (top CD) that may be the denominator of the depth:width aspect ratio—may be 200 nm or smaller, in various embodiments. In certain embodiments, the CD may be between 100 nm and 200 nm (forming a slit, for example), or between 40 nm and 80 nm (forming a contact hole, as another example).

An ideal feature profile of HAR channels 112 would be perfectly vertical and smooth, with a constant CD (equal to the top CD) throughout. In practice, HAR features may exhibit considerable variation from the ideal profile, such as tilting away from a surface normal; twisting around a surface normal; and variations in CD along the length of a channel. As illustrated in FIG. 1B, variations in CD may include tapering, such that a bottom critical dimension (bottom CD) of a HAR channel 112 may be substantially smaller than the top CD.

FIG. 1B also depicts bowing, in which the CD of a HAR channel 112 increases relative to the top CD and then decreases, creating a convexity or outward curvature in the feature profile. See also the descriptions below of FIGS. 4A and 4B, which illustrate a channel top 10 comprising portions of a HAR channel 112, the patterned mask layer 106, and the mask material layer 114. A maximum bowing, a position of the maximum bowing (with corresponding bow critical dimension, or bow CD), and a total length of bowing along HAR channels 112 may vary from channel to channel.

Bowing may generally occur near the top of a target layer for etching, such as the carbon-containing layer 104, and may be caused by diffraction or bending of the trajectories of ions of the plasma used to perform the etch. Changing the composition of the plasma (and thus a particular mix of ions present during the etching) may help to mitigate bowing, as enabled by embodiments.

Once the patterned carbon-containing layer 110 has been formed (in accordance with an embodiment), it may be used as a hard mask for a subsequent (conventional) etching process of the underlying material layer 102. FIG. 1C depicts the resulting formation of underlying HAR channels 120 in an etched underlying material layer 118. As illustrated, the subsequent etching removes the mask material layer 114, the patterned mask layer 106, and portions of the patterned carbon-containing layer 110, leaving behind a residual carbon-containing layer 122 comprising HAR channel bottoms 124. The thickness of the residual carbon-containing layer 122 may vary among embodiments and with a choice of subsequent etch chemistry and process conditions.

As illustrated in FIG. 1C, the subsequent etch may extend the underlying HAR channels 120 downward such that they reach an upper surface of the bottom layer 100. Accordingly, the subsequent etch chemistry may be chosen (in various embodiments) for selectivity to silicon or other components of the bottom layer 100 as well as to the hard mask (i.e., to the patterned carbon-containing layer 110, comprising amorphous carbon in some embodiments). A polymer deposited on the upper surface of the bottom layer 100 before deposition of the underlying material layer 102 may serve as an etch stop layer, in certain embodiments.

In embodiments with an underlying material layer 102 comprising a dielectric such as silicon oxide, the subsequent etch may comprise a fluorocarbon etching gas. The fluorocarbon may be unsaturated (comprising at least one carbon-carbon double or triple bond) or saturated (comprising only single bonds between carbons) and may be singly fluorinated, polyfluorinated, or perfluorinated (comprising no carbon-hydrogen bonds). For example, suitable saturated fluorocarbons may include fluoroform (CHF₃), carbon tetrafluoride (CF₄), octafluoropropane (C₃F₈), octafluorocyclobutane (C₄F₈), perfluorobutane (C₄F₁₀), or perflenapent (C₅F₁₂). Suitable unsaturated fluorocarbons may include hexafluoropropylene (C₃F₆), octafluoro-2-butene (C₄F₈), hexafluorobutadiene (C₄F₆), hexafluoro-2-butyne (C₄F₆), or hexafluorocyclobutene (C₄F₆). The fluorocarbon etching gas may comprise two or more fluorocarbons in order to achieve a desired stoichiometric carbon:fluorine ratio.

The subsequent etch may further comprise a balancing gas (such as oxygen) and/or an inert diluent gas (such as argon) in order to achieve an effective carbon:fluorine ratio in the subsequent etch chemistry different from the stoichiometric carbon:fluorine ratio. For example, a composition of the subsequent etch may be chosen to yield an effective carbon:fluorine ratio between 1:4 and 1:2, as may be appropriate for HAR etching of silicon oxide.

In some embodiments, the subsequent etch may be performed as a continuous process in the same apparatus used for low-temperature etching of the carbon-containing layer 104. In other embodiments, the subsequent etch may be performed using separate apparatus. For example, in one embodiment, low-temperature etching of the carbon-containing layer 104 may be performed in an ICP etching apparatus comprising a substrate holder configured to cool the substrate, and the subsequent etch of the underlying material layer 102 may be performed in a separate CCP etching apparatus. In still other embodiments, the etching processes may be performed within different processing chambers of a clustered system, the respective etch tools being connected by intermediary chambers with controlled atmospheric composition, pressure, and other conditions (in various embodiments).

While FIG. 1C depicts a direct transfer of features from the patterned carbon-containing layer 110 to the etched underlying material layer 118, feature profiles of the underlying HAR channels 120 may vary in practice, according to embodiments and to a choice of subsequent etching chemistry and process conditions. Without committing to any particular mechanism, one source of variation may be a change in total aspect ratio of the HAR features during the subsequent etch:The deeper mask channels 116 and the HAR channels 112 in the patterned carbon-containing layer 110 may (taken together) be characterized by a certain initial aspect ratio, and as the underlying HAR channels 120 are formed and portions of the higher-lying layers are etched away, the total aspect ratio may decrease. Aspect ratio-dependent etching effects may therefore modify the etch behavior (and thus the feature profile of the underlying HAR channels 120) in a time-dependent fashion. Consequently, actual profiles of the underlying HAR channels 120 may be more or less ideal than depicted.

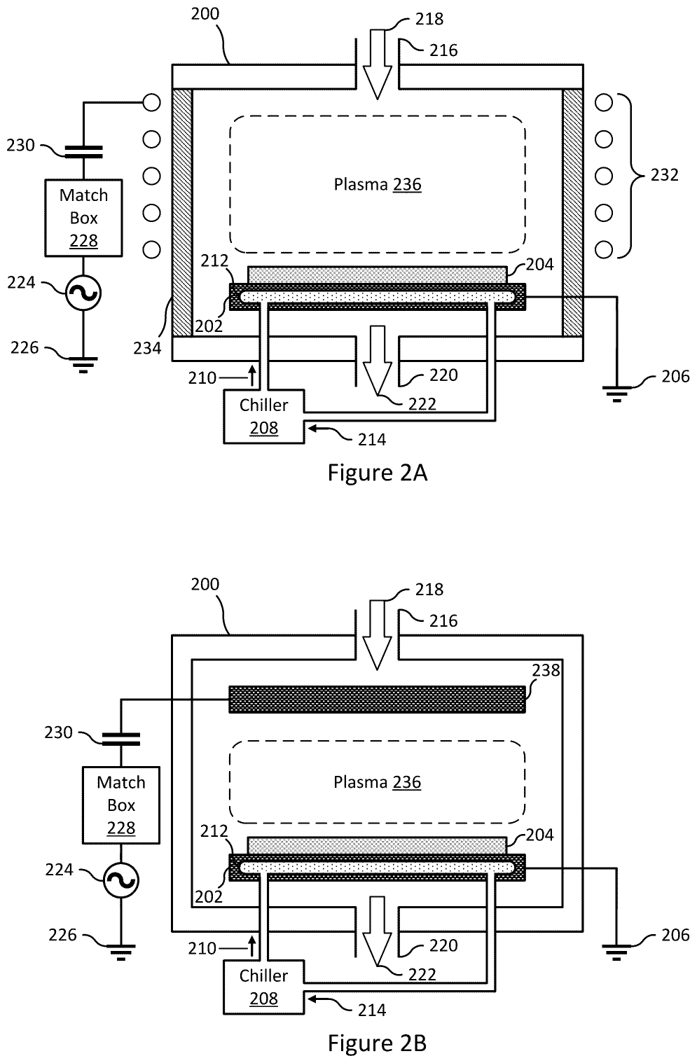

Embodiments of the low-temperature etching methods described herein enable formation of HAR features in carbon-containing layers with improved profiles through advantageous choices of etch chemistry and process conditions, and in particular through carrying out the etching at low temperatures comprising a deep freeze or cryogenic conditions. Details of embodiment etch chemistries and process conditions will now be described with reference to FIGS. 2A and 2B. These figures illustrate cross-sectional schematic views of apparatus for generating inductively coupled plasma and capacitively coupled plasma, respectively, to etch a substrate disposed over a cooled substrate holder, in accordance with various embodiments.

In the ICP etching apparatus of FIG. 2A, a processing chamber 200 is configured to contain a substrate 204 disposed over a substrate holder 202. In embodiments, the substrate holder 202 may be cooled below freezing, and in some embodiments may be cooled to cryogenic temperatures. In various embodiments, the substrate holder 202 may be coupled to a chiller 208 comprising thermocouples, control circuitry, tanks containing cooled liquids (also referred to herein as working fluids), piping, tubing, valves, pressure sensors, flow sensors, pumps, and the like. The chiller 208 may be configured to establish and maintain temperatures within a target range, for example, between −200° C. (73 K) and 0° C. (273 K).

In embodiments, a first temperature at which the etching is performed may be between −150° C. and −80° C. Temperatures below −100° C. correspond to “high-temperature” cryogenic conditions and may be achieved (in various embodiments) through the use of at least one working fluid with well-matched boiling temperature T_{b}, such as liquid xenon (T_{b}=−108° C.) or liquid krypton (T_{b}=−153° C.). Alternately, and in some embodiments, a colder working fluid may be used, such as liquid nitrogen (T_{b}=−196° C.). Liquid nitrogen may be more widely available and thus more economical than working fluids more closely matched to the first temperature, in certain embodiments.

In other embodiments, the first temperature may be between −100° C. and −40° C. Temperatures above-100° C. may be established in embodiments with conventional deep-freezing techniques employing standard refrigerant working fluids such as R-404a (a blend of fluorinated ethanes with T_{b}=−47° C.) or R-508b (a blend of fluoroform (CHF₃) and hexafluoroethane (C₂F₆) with T_{b}=−87° C.). Some embodiments may comprise a first temperature in a range spanning cryogenic conditions and deep-freezing, such as between −150° C. and −40° C., and may employ both types of working fluid.

Whatever range of temperatures may be selected in an embodiment, the chiller 208 may cool the substrate 204 by establishing a thermal coupling between a suitably cold working fluid and the substrate holder 202. Physical contact (and associated thermal coupling) between the substrate holder 202 and the substrate 204 then causes the desired cooling of the substrate 204. In some embodiments, the working fluid may be circulated at low temperature from a fluid out-flow 210 into a coolant channel 212 within the substrate holder 202 before returning to the chiller 208 through a fluid in-flow 214 at the same or higher temperature (having cooled the substrate holder 202 and the substrate 204). In various embodiments, the composition, temperature, and flow rate of the working fluid may be tunable as needed for process optimization and control.

The coolant channel 212 may (in some embodiments) comprise one or more openings within the substrate holder 202 allowing passage of non-insulated piping or tubing to conduct the working fluid, or (in other embodiments) may be coated in a liner material allowing direct physical contact (and thus thermal coupling) between the working fluid and the substrate holder 202 itself. In certain embodiments, the coolant channel 212 may comprise a single meander through a horizontal cross-section of the substrate holder 202. In other embodiments, the coolant channel 212 may comprise a network of interconnected channels that diverge from the fluid out-flow 210, covering a horizontal cross-section of the substrate holder 202, before converging again at the fluid in-flow 214. In certain embodiments, the coolant channel 212 may serve to circulate any of several working fluids, or additional coolant channels may be configured within the substrate holder 202 and coupled to the chiller 208 to allow for the sequential or parallel circulation of several working fluids in isolation from each other.

In some embodiments, though not as illustrated, the substrate holder 202 may further comprise a backside-gas system to improve heat transfer between the substrate 204 and the substrate holder 202. Use of a backside-gas system may be advantageous for embodiments in which the carbon-containing layer 104 comprises amorphous carbon, given the lower thermal conductivities and higher heat capacities typical of disordered substances. Improved thermal coupling between the substrate 204 and the substrate holder 202 may reduce cooling dwell times before initiation of the etching.

In such embodiments, the backside-gas system may comprise a network of grooves etched into the surface of the substrate holder 202 adjacent to the substrate 204, through which a thermally conductive gas may be circulated. (In some such embodiments, the thermally conductive gas may be helium. Helium is largely chemically inert, is unlikely to perturb the properties of an etching plasma, and does not liquefy within embodiment temperature ranges.) A gas injector-distinct from the working fluid in-flow 214 and out-flow 210 used to circulate the cryogenic working fluid within the coolant channel 212—may be employed to introduce the thermally conductive gas into the system and regulate its pressure.

The pressure of thermally conductive gas between the substrate holder 202 and the substrate 204 may be maintained in a range between 5 and 20 torr, optimizing heat transfer while avoiding undesirable mechanical stresses on the substrate 204 that may (for example) cause warping of the wafer. Any thermally conductive gas escaping from under the substrate 204 may be drawn by prevailing process gas flows toward a gas outlet 220 to be vented, as described in further detail below.

In some embodiments, the substrate holder 202 may be cooled at least part of the way from an ambient temperature to the first temperature before the substrate 204 is loaded. In some such embodiments, the substrate holder 202 may be cooled to freezing (0° C.) before loading of the substrate 204. In other embodiments, the substrate holder 202 may be cooled some or all of the way from an ambient temperature to the first temperature with the substrate 2024 loaded over it. In still other embodiments, the substrate holder 202 may be held at a lower temperature than the ambient temperature continuously in order to accelerate fabrication and increase etching throughput.

In some embodiments, a process by which the substrate holder 202 (and thus the substrate 204, once loaded) is cooled to within the range contemplated for the first temperature may comprise cooling at a constant rate (e.g., a certain number of ° C. per minute) over a corresponding (first) time period. In some such embodiments, the first time period for the cooling may last up to 30 minutes; for example, the first time period may last between 10 minutes and 30 minutes.

In other embodiments, the cooling process may comprise stages of varying duration and rates of cooling, such as an initial rapid cooling from ambient temperature to freezing (0° C.); an intermediate slow cooling from freezing to the first temperature; and a final stabilization stage while maintaining the first temperature. Staged cooling may help to prevent damage from thermal shock to the substrate 204 (or to the etching apparatus and its components) while shortening total cooling times and ensuring temperature uniformity across the substrate 204 and the substrate holder 202. In embodiments with a cooling process comprising stages, the sum of the durations of the stages may be the first time period for the cooling.

In certain embodiments comprising staged cooling, the initial rapid cooling may have a duration between 1 and 5 minutes; the intermediate slow cooling may have a duration between 3 and 10 minutes; and the final stabilization stage may have a duration between 15 seconds and 2 minutes. Correspondingly, and in various embodiments, the staged cooling may have a first time period lasting between 4 and 20 minutes. In other embodiments comprising staged cooling and either pre-cooling or a continuously maintained lower-than-ambient temperature of the substrate holder 202, the initial rapid cooling stage may be abbreviated or omitted, with a corresponding reduction in the first time period for the staged cooling.

According to various embodiments, the substrate holder 202 may be maintained at the first temperature once it has been established. In these embodiments, maintaining the first temperature may comprise controlling fluctuations (relative to the first temperature) of a measured temperature of the substrate holder 202 to a magnitude of 2° C. Maintaining the first temperature of the substrate holder 202 may help first to stabilize and then to maintain a corresponding (second) temperature of the substrate 204. In embodiments characterized by sufficiently close thermal coupling and efficient heat transfer between the substrate holder 202 and the substrate 204, the second temperature may match the first temperature; in other embodiments, the second temperature may be different from (but close to) the first temperature, while still within the contemplated range.

In various embodiments, stabilizing the substrate 204 at the second temperature may occur over a second time period, through physical contact (and thus thermal coupling) with the substrate holder 202. In some embodiments, the second time period may be non-overlapping with the first time period; in other embodiments, the second time period may overlap with any portion of the first time period after the first temperature of the substrate holder 202 has been established. In certain of the latter embodiments also comprising staged cooling of the substrate holder 202, the second time period may overlap or be simultaneous with the final stabilization stage. In various embodiments, the second time period may last between 15 seconds and 2 minutes.

Various control systems and approaches may be incorporated into the chiller 208 in order to ensure maintenance of the first temperature of the substrate holder 202. In some embodiments, a proportional-integral-derivative (PID) temperature controller may be used to limit fluctuations (deviations from the first temperature) of the measured temperature of the substrate holder 202 to a variation of 0.1%. For example, in embodiments comprising a first temperature of −100° C., a PID control scheme may achieve temperature maintenance to within a magnitude of 0.1° C.

Some embodiments may further incorporate control techniques such as cascade control (embedding a control loop for the first temperature of the substrate holder 202 within an outer control loop for the working fluid in the coolant channel 212) or model predictive control (based on thermal modeling of the substrate 204 in contact with the substrate holder 202). In embodiments for which precision temperature control is determined to be critical, these and other methods may be used along with apparatus modifications (such as the use of high-thermal mass components) to limit temperature fluctuations further, such as (in an embodiment) to within a magnitude of 0.01° C.

Once the substrate holder 202 has been cooled to maintain the first temperature selected in a given embodiment, and once the substrate 204 has been correspondingly stabilized at the second temperature, delivery of process gases to the processing chamber 200 may prepare the substrate 204 for low-temperature etching. With further reference to FIG. 2A, the etching apparatus comprises a gas inlet 216 to permit a gas in-flow 218 of process gases into the processing chamber 200. A gas outlet 220 allows for pressure control within the processing chamber 200 as well as charging, continuous flow, or evacuation of the process gases, as indicated by gas out-flow 222. The gas inlet 216 and gas outlet 220 may further be coupled to and controlled by a gas flow control system comprising control circuitry, gas canisters, piping, tubing, valves, pressure sensors, flow sensors, pumps, and the like.

In some embodiments, the gas inlet 216 may comprise a set of multiple gas inlets, allowing (for example) isolated flow and delivery into the processing chamber 200 of gases that might otherwise react before reaching the processing chamber 200. In these embodiments, the process gases may mix and thereby form a gas mixture within the processing chamber 200 subsequent to delivery. In other embodiments, the gas inlet 216 may comprise a gas mixer, such that a homogeneous gas mixture may be delivered into the processing chamber 200. The gas outlet 220 may comprise a set of multiple gas outlets. In some embodiments, the gas outlet 220 may comprise a set of multiple gas outlets.

Etch chemistries for use in various embodiments of the low-temperature etching may comprise an etching gas comprising oxygen (such as elemental oxygen, O₂) and a passivating gas comprising silicon and fluorine (such as tetrafluorosilane, SiF₄). In some embodiments, an etch chemistry may further comprise a sulfur-containing gas (such as carbonyl sulfide, COS or sulfur dioxide, SO₂), a hydrogen-containing gas (such as elemental hydrogen, H₂), or both.

In some embodiments, the passivating gas may comprise tetrafluorosilane (SiF₄). In other embodiments, the silicon:fluorine ratio (and thus the aggressiveness) of the etch chemistry may be tuned by selecting a passivating gas comprising other fluorinated silanes, in combination with or in place of the perfluorinated SiF₄. In various embodiments, the passivating gas may comprise a fluorinated silane with formula SiHₙF₄₋ₙ, and 0≤n≤3. Irrespective of which fluorinated silane (or mixture thereof) may be selected, formation of a SiOₓF_{y} film on the surface and sidewalls of the carbon-containing layer 104 (and subsequently of the patterned carbon-containing layer 110, with respective references to FIGS. 1A and 1B) during etching may provide advantageous passivation, mitigating or preventing bowing and other feature profile variations while also being easily removed by warming the substrate. Any hydrogen from the passivating gas may further serve (without committing to any particular mechanism) to scavenge fluorine and to advantageously improve the volatilization of the passivation layer. As a result, embodiment methods may yield a cleaner surface post-etch than conventional methods.

According to various embodiments comprising the etching gas and the passivating gas, a first flow rate of the etching gas may be between 50 sccm (standard cubic centimeters per minute) and 1000 sccm, and a second flow rate of the passivating gas may be between 2 sccm and 200 sccm. In some embodiments, a ratio of the first flow rate of the etching gas and the second flow rate of the passivating gas may be between 1:1 and 50:1, such that the etching gas is the predominant species in the gas mixture and a rate of etching may be sufficiently high to maintain throughput. In some such embodiments, the ratio of the first flow rate and the second flow rate may be 10:1. In other embodiments, the ratio may be between 1:10 and 1:1, yielding an overpassivated chemistry that may be appropriate for forming surface textures or protecting sensitive device structures during etching.

Some embodiments may further comprise flowing a hydrogen-containing gas while simultaneously flowing the etching gas and the passivating gas. Without committing to any particular theory, the hydrogen-containing gas may be included among the process gases in order to enhance dissociation of O₂ in the plasma 236 (with reference to FIGS. 2A and 2B); to increase the number of reactive species (such as oxygen radicals) present in the plasma 236; and to adjust the silicon:fluorine ratio in the plasma 236 by scavenging of fluorine. Any hydrogen from the passivating gas may also contribute to these advantageous features in the plasma 236.

In some embodiments, the hydrogen-containing gas may comprise elemental hydrogen (H₂). In various embodiments, the passivating gas and the hydrogen-containing gas may be flowed at rates totaling between 10 sccm and 200 sccm, with the hydrogen-containing gas flowed at 5% or less of the rate of the passivating gas. (In other words, in such embodiments, the hydrogen-containing gas may be an additive.) In other embodiments, the hydrogen-containing gas may separately be flowed at a rate between 5 sccm and 50 sccm.

Taken together, etch chemistries comprising the etching gas and the passivating gas, with or without the hydrogen-containing gas—and without the sulfur-containing gas—enable, in various embodiments, deep etching of HAR channels 112 (with reference to FIG. 1B) with improved sidewall protection (greater anisotropy), with less residue left behind (including a total elimination of sulfur oxyacid contamination), and with a wider process window than conventional methods. These etch chemistries may be most advantageous when performed under high-temperature cryogenic conditions or under a very deep freeze (for example, at a first temperature between −150° C. and −80° C., in various embodiments). Other embodiment etch chemistries may enable etching at less extreme temperatures and may thereby reduce energy and material costs associated with cooling the substrate.

In various such embodiments, the etch chemistry may comprise the etching gas and the passivating gas, as described above, as well as the sulfur-containing gas. (These etch chemistries may further comprise the hydrogen-containing gas, in some embodiments.) In some embodiments, the sulfur-containing gas may comprise sulfur dioxide (SO₂). In other embodiments, the sulfur-containing gas may comprise carbonyl sulfide (often written COS, but with structural formula O═C═S).

While etch chemistries comprising sulfur may present some risk of sulfur oxyacid contamination, the inventors have nevertheless observed multiple advantageous synergistic effects of combining fluorinated silane-based passivation with sulfur-based passivation in a low-temperature etch. In particular, and with reference to FIG. 1B, embodiment methods show increased deposition of the mask material layer 114 relative to sulfur-only passivation and smoother feature profiles relative to fluorinated silane-only passivation. Moreover, bowing is significantly reduced by embodiment methods relative to both single-passivating gas approaches. These advantages are described in further detail below.

According to various embodiments, a first flow rate of the etching gas may be between 50 sccm and 1000 sccm; a second flow rate of the passivating gas may be between 5 sccm and 100 sccm; and a third flow rate of the sulfur-containing gas may also be between 5 sccm and 100 sccm. In some embodiments, a ratio of the first flow rate of the etching gas, the second flow rate of the passivating gas, and the third flow rate of the sulfur-containing gas may be 1:1:1 and 10:1:1, such that the etching gas is the predominant species in the gas mixture and a rate of etching may be sufficiently high to maintain throughput. In some such embodiments, the ratio of the first flow rate, second flow rate, and third flow rate may be 5:1:1. In some embodiments, flow rates of the passivating gas and the sulfur-containing gas may be selected separately, such that a ratio of the first flow rate may be between 1:1 and 10:1, while a ratio of the second flow rate and the third flow rate may separately be between 1:2 and 2:1.

Some embodiments comprising the sulfur-containing gas may further comprise flowing the hydrogen-containing gas while simultaneously flowing the etching, passivating, and sulfur-containing gases. In various embodiments, the passivating gas, the sulfur-containing gas, and the hydrogen-containing gas may be flowed at rates totaling between 10 sccm and 200 sccm, with the hydrogen-containing gas flowed at 5% or less of the combined rates of the passivating gas and the sulfur-containing gas. (In other words, in such embodiments, the hydrogen-containing gas may be an additive.) In other embodiments, the hydrogen-containing gas may separately be flowed at a rate between 5 sccm and 50 sccm.

In various embodiments comprising any of the etch chemistries described above, a total pressure of process gases in the processing chamber 200 may be between 1 mtorr and 50 mtorr. In some embodiments, the total pressure of process gases may between 5 mtorr and 30 mtorr.

With further reference to FIG. 2A and the ICP etching apparatus it depicts, a plasma 236 may be generated and subsequently sustained within the processing chamber once the process gases have been established at a selected total pressure. In order to generate the plasma 236, an RF power supply 224 may be coupled to an inductive coil 232 winding around the processing chamber 200. (The small circles in the figure represent cross-sections of the inductive coil as it passes through the sectioning plane.) The RF power supply 224 may be connected to a ground 226 and coupled to the inductive coil 232 through impedance-matching circuitry (match box 228) and a blocking capacitor 230. According to various embodiments, the RF power supply may operate at high frequency, at very high frequency, or in higher-frequency regimes.

The inductive coil 232 may be coupled to the interior of the processing chamber 200 by dielectric windows 234, which allow the induced RF field to penetrate into the chamber in order to generate (and subsequently sustain) a plasma 236 comprising at least one process gas. In some embodiments, a separate (continuous wave or pulsed) RF bias may be applied to the substrate holder 202 to assist in sustaining the plasma 236. In other embodiments, and as illustrated, the substrate holder 202 may be connected to a ground 206. In still other embodiments, the ground 206 may be a chassis ground connected to processing chamber 200, with the substrate holder 202 floating.

In some embodiments, a CCP etching apparatus like that illustrated in FIG. 2B may be used instead of the ICP etching apparatus of FIG. 2A. (Like reference numerals are used to label like structures in the two figures.) The principal difference in the CCP etching apparatus is that the circuit elements associated with RF power (i.e., the RF power supply 224, the (RF-connected) ground 226, the match box 228, and the blocking capacitor 230) may be connected to an upper electrode 238 rather than to the inductive coil 232. In such embodiments, the upper electrode 238 works in conjunction with the substrate holder 202 (which functions as a lower electrode) to impose a potential difference that generates and subsequently sustains the plasma 236.

The ICP and CCP etching apparatus depicted in FIGS. 2A and 2B are intended as examples of embodiments. In other embodiments, an ICP etching apparatus may comprise a planar inductive coil disposed over a top dielectric window in the processing chamber 200. Still other embodiments may comprise an electron cyclotron resonance (ECR) plasma source or a helical resonator, or other plasma technologies.

Irrespective of how the plasma 236 may be generated in any given embodiment, the low-temperature etching may be performed by exposing the substrate 204 to the plasma 236 while maintaining the first temperature of the substrate holder 202 and after stabilizing the substrate 204 at the second temperature. With reference to FIG. 1B, exposure to the plasma 236 over a sufficient (third) period of time may have the effect of forming HAR channels 112 in the patterned carbon-containing layer 110. In some embodiments, a third time period lasting at least 5 minutes may form HAR channels 112 comprising an aspect ratio of at least 20:1.

While a process of active warming (whether single-step or staged) may be used after the low-temperature etching (in some embodiments), it may be sufficient in many embodiments to cease circulating working fluid from the chiller 208 through the coolant channel 212 and to allow the substrate 204 and the substrate holder 202 to return passively to ambient temperature. When ambient temperature has been reestablished throughout the processing chamber 200, the etched substrate depicted in FIG. 1B may be ready for further processing (such as the subsequent etch, yielding the etched underlying material layer 118 of FIG. 1C).

FIGS. 3A-3C provide flow charts for methods of etching a layer, and in particular for etching a carbon-containing layer of a substrate with process gases comprising an etching gas and a passivating gas, and while maintaining a first temperature of a substrate holder, according to various embodiments.

In the method of FIG. 3A, and beginning with box 301A, a substrate is loaded onto a substrate holder disposed within a processing chamber, the substrate comprising a carbon-containing layer and a patterned mask layer. Then, in box 302A, the substrate holder is cooled to a first temperature between −150° C. and −40° C. In box 303A, while maintaining the first temperature of the substrate holder, the carbon-containing layer is patterned to form a channel in the carbon-containing layer. The patterning comprises simultaneously flowing into the processing chamber an etching gas comprising oxygen and a passivating gas comprising silicon and fluorine, and generating a plasma within the processing chamber.

In the method of FIG. 3B, and beginning with box 301B, a substrate is loaded onto a substrate holder disposed within a processing chamber, the substrate comprising an amorphous carbon layer and a patterned mask layer. Then, in box 302B, the substrate holder is cooled to a first temperature between −100° C. and −40° C. In box 303B, while maintaining the first temperature of the substrate holder, the amorphous carbon layer is patterned to form a channel in the amorphous carbon layer. The patterning comprises simultaneously flowing into the processing chamber an etching gas comprising oxygen, a passivating gas comprising a fluorinated silane, and a sulfur-containing gas, and generating a plasma within the processing chamber.

In the method of FIG. 3C, and beginning with box 301C, a substrate is loaded onto a substrate holder, the substrate being thermally coupled to the substrate holder and comprising a carbon-containing layer and a patterned mask layer. Then, in box 302C, the substrate holder is cooled over a first time period to a first temperature between −150° C. and −40° C. In box 303C, while maintaining the first temperature of the substrate holder, the substrate is stabilized over a second time period at a second temperature. Next, in box 304C, and after the second time period, the substrate is exposed over a third time period to a plasma. The plasma is generated from a gas mixture comprising an etching gas and a passivating gas, the etching gas comprising oxygen and the passivating gas comprising silicon and fluorine.

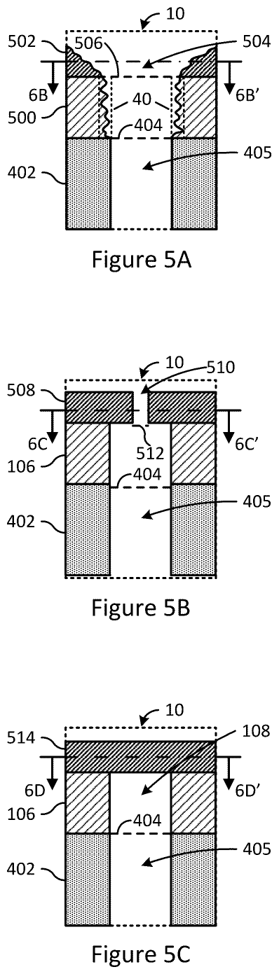

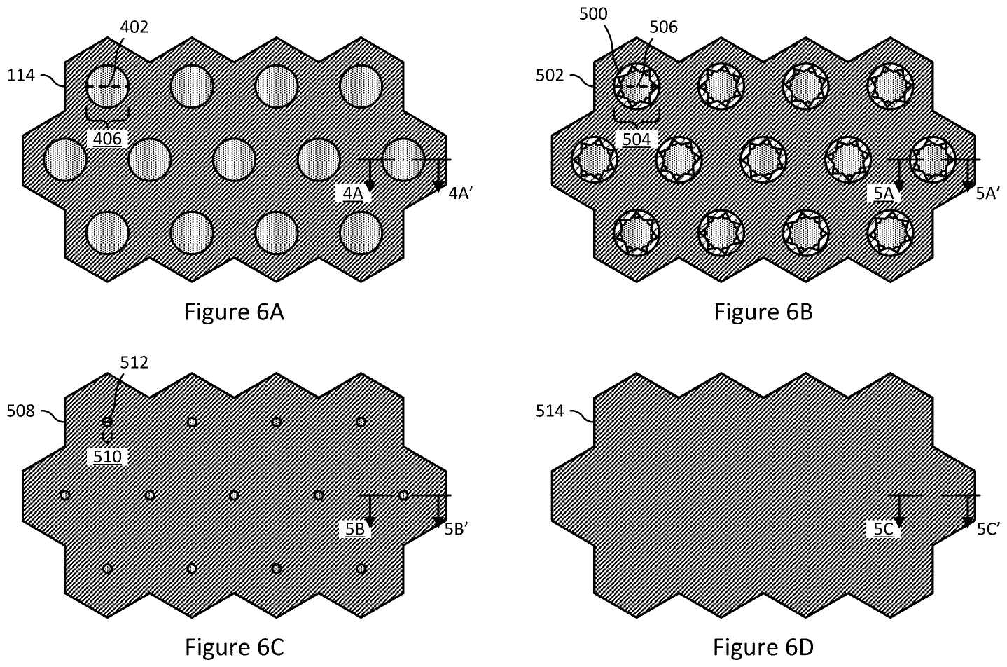

FIGS. 4A and 4B provide a cross-sectional comparison between channels formed by a hypothetical wholly anisotropic etching process and bowed channels formed in practice by anisotropic etching, according to embodiments. Throughout the discussion of FIGS. 4A and 4B—and subsequently of FIGS. 5A-5C, and FIGS. 6A-6D—deviations from ideal feature profile and/or mask deposition behavior will be illustrated individually. In practice, such deviations from the ideal may be exhibited simultaneously and in any combination, depending on a particular choice of etch chemistry and process conditions. Embodiments advantageously reduce the severity of these variations.

FIG. 4A illustrates an idealized channel profile resulting from a perfectly anisotropic etching process, and specifically an idealized version of the channel top 10 (with reference to FIG. 1B). In FIG. 4A, like structures from FIG. 1B are labeled with the corresponding reference numerals; note, however, that such labeling is intended to indicate hypothetical correspondences.

In FIG. 4A, HAR channel 112 has been formed in the carbon-containing layer 104, yielding a perfectly anisotropically etched carbon-containing layer 400 covered by the patterned mask layer 106 and mask material layer 114 (which together define a deeper mask channel 116). The width of the deeper mask channel 116 defines a top-down critical dimension (TDCD) 402 that may in practice be determined by (for example) scanning electron microscopy. FIG. 6A depicts a portion of a perfectly anisotropically etched substrate as might be observed in a scanning electron micrograph, with TDCD 402 once again indicated by a half-dashed line. (The correspondence between these figures is indicated by the sectioning line 6A-6A′ in FIG. 4A and the sectioning line 4A-4A′ in FIG. 6A.) While the deeper mask channels 116 (and the HAR channels 112 below) are depicted with circular cross sections, these channels may (in various embodiments) have any suitable shape.

The TDCD 402 may be equal to the top CD 404 of the idealized HAR channel 405 in the perfectly anisotropically etched carbon-containing layer 400, and both the TDCD 402 and the top CD 404 may further be equal to the bottom CD of the idealized HAR channel 405. In other words, in an idealized case, lateral etching is completely suppressed, and the idealized HAR channel 405 is perfectly vertical, with sidewalls forming right angles at the bottom of the channel.

By contrast, FIG. 4B depicts a more realistic channel profile. In particular, while the overall etching illustrated in 1B is indeed highly anisotropic, the channel top 10 exhibits bowing. While the TDCD 402 and top CD 404 still match, the bow CD 406 may be measurably larger in electron micrographs (e.g., as illustrated, a ratio between the top CD 404 and the bow CD 406 of approximately 2:3). The inventors have observed that embodiment methods improve channel profiles of patterned carbon-containing layer 110 by reducing the bow CD 406 and bringing the ratio between top CD 404 and bow CD 406 closer to 1:1. According to various embodiments, the ratio between top CD 404 and bow CD 406 may be at least 2:3. One such embodiment may comprise the sulfur-containing gas and a ratio of the flow rates of the etching gas, the passivating gas, and the sulfur-containing gas selected to be 5:1:1.

In FIGS. 4A and 4B, the patterned mask layer 106 and mask material layer 114 have been illustrated with idealized profiles, with smooth sidewalls and perfect alignment between the layers, yielding a deeper mask channel 116 with TDCD 402 equal to the top CD 404. In practice, because of the highly complicated etching and (re-) deposition dynamics that may occur during etching of the carbon-containing layer 104, the deeper mask channels 116 may have profiles that vary considerably from the ideal. FIGS. 5A-5C provide a cross-sectional comparison among several observed variations in the profile of deeper mask channels 116, complemented by the top-down views of FIGS. 6B-6D. Sectioning lines in these figures indicate the correspondence.

A phenomenon that may occur during etching of the carbon-containing layer 104 is roughening of the patterned mask layer 106, as illustrated in FIGS. 5A and 6B. Etching of the carbon-containing layer 104 may partially etch the patterned mask layer 106 (forming a roughened mask layer 500) and may also deposit a rough mask material layer 502 with a sloped profile and varying thickness across its upper surface. A resulting roughened mask channel 504 may have a larger TDCD 506 than TDCD 402. Such deviations from the ideal in the profile of the roughened mask channel 504 may contribute to greater variability in the underlying HAR channels 120 when etched.

Sidewalls 40 of the roughened mask layer 500 may be identified by drawing a rectangle around its inner boundary, as indicated by half-dashed lines. A roughness of the roughened mask layer 500 may be quantified in terms of a width of a larger of the sidewalls 40 written as a percentage of the top CD 404, i.e.,

$$roughness = \frac{width of larger sidewall}{top critical dimension} \times 100 \% \qquad ( Equation 1 )$$

According to various embodiments, the roughness may be limited to 5%, and in many embodiments may be smaller, advantageously for the subsequent etch. One such embodiment may comprise the sulfur-containing gas and a ratio of the flow rates of the etching gas, the passivating gas, and the sulfur-containing gas selected to be 5:1:1.

Another effect that may be observed subsequent to etching of the carbon-containing layer 104 is clogging of the mask, as depicted in FIGS. 5B and 6C. (Clogging may occur, for example, when attempting to etch the carbon-containing layer 104 at temperatures above the cooled or cryogenic conditions of embodiment methods.) Excessive deposition of mask material may result in an overgrown mask material layer 508 that is no longer aligned with the patterned mask layer 106 and may extend past it, partially covering the idealized HAR channel 405. As a result, a clogged mask channel 510 may form with a smaller TDCD 512 than the top CD 404. Variable clogging may compromise the uniformity of the etch. Indeed, clogging may slow and even stop etching of the carbon-containing layer 104, leading to overall process failure.

In the most severe cases illustrated by FIGS. 5C and 6D, total coverage by a mask material blanket layer 514 may occur. In this scenario, the mask material blanket layer 514 completely covers the mask channel 108, preventing any further etching and making it impossible to achieve the desired channel depth or profile.

In practice, the overgrown mask material layer 508 or the mask material blanket layer 514 may extend downward along sidewalls of the patterned mask layer 106, partially covering them. Downward extension of these layers has been omitted from FIGS. 5B and 5C in order to emphasize the importance of lateral extension.

FIGS. 4B, 5A-5C, and 6B-6D highlight many existing challenges to the formation of ideal and uniform feature profiles in the HAR channels 112 (by etching of the carbon-containing layer 104) and the underlying HAR channels 120 (by the subsequent etch). By mitigating the severity of these effects—and by yielding a cleaner etched substrate, in some embodiments without any sulfur oxyacid contamination—embodiment methods enable the formation of HAR features suitable for advanced logic, integration, and memory applications.

Example embodiments of the invention are described below. Other embodiments can also be understood from the entirety of the specification as well as the claims filed herein.

Example 1. A method for etching a layer, the method including: loading a substrate onto a substrate holder disposed within a processing chamber, the substrate including a carbon-containing layer and a patterned mask layer; cooling the substrate holder to a first temperature between −150° C. and −40° C.; and while maintaining the first temperature of the substrate holder, patterning the carbon-containing layer to form a channel in the carbon-containing layer, the patterning including: simultaneously flowing into the processing chamber an etching gas including oxygen and a passivating gas including silicon and fluorine; and generating a plasma within the processing chamber.

Example 2. The method of example 1, where cooling the substrate holder includes flowing a cooled liquid through channels disposed within the substrate holder.

Example 3. The method of one of examples 1 or 2, further including cooling the substrate through thermal coupling to the substrate holder.

Example 4. The method of one of examples 1 to 3, where maintaining the first temperature of the substrate holder includes controlling temperature fluctuations of the substrate holder relative to the first temperature to a magnitude between 0° C. and 2° C.

Example 5. The method of one of examples 1 to 4, where the carbon-containing layer includes amorphous carbon.

Example 6. The method of one of examples 1 to 5, where the passivating gas includes SiHₙF₄₋ₙ with 0≤n≤3.

Example 7. The method of one of examples 1 to 6, further including flowing a sulfur-containing gas into the processing chamber while simultaneously flowing the etching gas and the passivating gas.

Example 8. The method of one of examples 1 to 7, where the sulfur-containing gas includes sulfur dioxide or carbonyl sulfide.

Example 9. The method of one of examples 1 to 8, further including flowing a hydrogen-containing gas into the processing chamber while simultaneously flowing the etching gas and the passivating gas.

Example 10. The method of one of examples 1 to 9, where the hydrogen-containing gas includes H₂.

Example 11. The method of one of examples 1 to 10, where a first flow rate of the etching gas is between 50 sccm and 1000 sccm and a second flow rate of the passivating gas is between 2 sccm and 200 sccm.

Example 12. The method of one of examples 1 to 11, where a ratio of a first flow rate of the etching gas and a second flow rate of the passivating gas is between 1:1 and 50:1.

Example 13. The method of one of examples 1 to 12, where a ratio of a first flow rate of the etching gas and a second flow rate of the passivating gas is between 1:10 and 1:1.

Example 14. The method of one of examples 1 to 13, where selecting a time period of exposure of the substrate to the plasma lasting at least 5 minutes forms a channel in the carbon-containing layer including an aspect ratio of at least 20:1.

Example 15. A method for etching a layer, the method including: loading a substrate onto a substrate holder disposed within a processing chamber, the substrate including an amorphous carbon layer and a patterned mask layer; cooling the substrate holder to a first temperature between −100° C. and −40° C.; and while maintaining the first temperature of the substrate holder, patterning the amorphous carbon layer to form a channel in the amorphous carbon layer, the patterning including: simultaneously flowing into the processing chamber an etching gas including oxygen, a passivating gas including a fluorinated silane, and a sulfur-containing gas; and generating a plasma within the processing chamber.

Example 16. The method of example 15, where the sulfur-containing gas includes sulfur dioxide or carbonyl sulfide.

Example 17. The method of one of examples 15 or 16, where a first flow rate of the etching gas is between 50 sccm and 1000 sccm, a second flow rate of the passivating gas is between 5 sccm and 100 sccm, and a third flow rate of the sulfur-containing gas is between 5 sccm and 100 sccm.

Example 18. The method of one of examples 15 to 17, where a ratio of a first flow rate of the etching gas, a second flow rate of the passivating gas, and a third flow rate of the sulfur-containing gas is between 1:1:1 and 10:1:1.

Example 19. The method of one of examples 15 to 18, where a ratio of the first flow rate and the second flow rate is between 1:1 and 10:1, and where a ratio of the second flow rate and the third flow rate is between 1:2 and 2:1.

Example 20. The method of one of examples 15 to 19, further including selecting a ratio of a first flow rate of the etching gas, a second flow rate of the passivating gas, and a third flow rate of the sulfur containing gas to be 5:1:1.

Example 21. A method for etching a layer, the method including: loading a substrate onto a substrate holder disposed within a processing chamber, the substrate being thermally coupled to the substrate holder, the substrate including a carbon-containing layer and a patterned mask layer; over a first time period, cooling the substrate holder to a first temperature between-150° C. and −40° C.; while maintaining the first temperature of the substrate holder, stabilizing the substrate at a second temperature over a second time period; and after the second time period, exposing the substrate to a plasma over a third time period, the plasma being generated from a gas mixture including an etching gas and a passivating gas, the etching gas including oxygen, the passivating gas including silicon and fluorine.

Example 22. The method of example 21, where the gas mixture further includes a sulfur-containing gas.

Example 23. The method of one of examples 21 or 22, where cooling the substrate holder includes a constant rate of cooling, the first time period lasting between 10 minutes and 30 minutes.

Example 24. The method of one of examples 21 to 23, where cooling the substrate holder includes stages, each stage including a constant rate of cooling and a duration, a sum of the durations of the stages equaling the first time period.

Example 25. The method of one of examples 21 to 24, where stabilizing the substrate includes cooling the substrate through physical contact with the substrate holder for a second time period lasting between 15 seconds and 2 minutes.

Example 26. The method of one of examples 21 to 25, where selecting a third time period lasting at least 5 minutes forms a channel in the carbon-containing layer including an aspect ratio of at least 20:1.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. A method for etching a layer, the method comprising:
loading a substrate onto a substrate holder disposed within a processing chamber, the substrate comprising a carbon-containing layer and a patterned mask layer;
cooling the substrate holder to a first temperature between −150° C. and −40° C.; and
while maintaining the first temperature of the substrate holder, patterning the carbon-containing layer to form a channel in the carbon-containing layer, the patterning comprising:
simultaneously flowing into the processing chamber an etching gas comprising oxygen and a passivating gas comprising silicon and fluorine; and
generating a plasma within the processing chamber.

2. The method of claim 1, wherein cooling the substrate holder comprises flowing a cooled liquid through channels disposed within the substrate holder.

3. The method of claim 1, wherein maintaining the first temperature of the substrate holder comprises controlling temperature fluctuations of the substrate holder relative to the first temperature to a magnitude between 0° C. and 2° C.

4. The method of claim 1, wherein the carbon-containing layer comprises amorphous carbon.

5. The method of claim 1, wherein the passivating gas comprises SiHₙF₄₋ₙ with 0≤n≤3.

6. The method of claim 1, further comprising flowing a sulfur-containing gas into the processing chamber while simultaneously flowing the etching gas and the passivating gas.

7. The method of claim 6, wherein the sulfur-containing gas comprises sulfur dioxide or carbonyl sulfide.

8. The method of claim 1, wherein a ratio of a first flow rate of the etching gas and a second flow rate of the passivating gas is between 1:1 and 50:1.

9. The method of claim 1, wherein selecting a time period of exposure of the substrate to the plasma lasting at least 5 minutes forms a channel in the carbon-containing layer comprising an aspect ratio of at least 20:1.

10. A method for etching a layer, the method comprising:
loading a substrate onto a substrate holder disposed within a processing chamber, the substrate comprising an amorphous carbon layer and a patterned mask layer;
cooling the substrate holder to a first temperature between −100° C. and −40° C.; and
while maintaining the first temperature of the substrate holder, patterning the amorphous carbon layer to form a channel in the amorphous carbon layer, the patterning comprising:
simultaneously flowing into the processing chamber an etching gas comprising oxygen, a passivating gas comprising a fluorinated silane, and a sulfur-containing gas; and
generating a plasma within the processing chamber.

11. The method of claim 10, wherein the sulfur-containing gas comprises sulfur dioxide or carbonyl sulfide.

12. The method of claim 10, wherein a ratio of a first flow rate of the etching gas, a second flow rate of the passivating gas, and a third flow rate of the sulfur-containing gas is between 1:1:1 and 10:1:1.

13. The method of claim 12, wherein a ratio of the first flow rate and the second flow rate is between 1:1 and 10:1, and wherein a ratio of the second flow rate and the third flow rate is between 1:2 and 2:1.

14. The method of claim 10, further comprising selecting a ratio of a first flow rate of the etching gas, a second flow rate of the passivating gas, and a third flow rate of the sulfur containing gas to be 5:1:1.

15. A method for etching a layer, the method comprising:
loading a substrate onto a substrate holder disposed within a processing chamber, the substrate being thermally coupled to the substrate holder, the substrate comprising a carbon-containing layer and a patterned mask layer;
over a first time period, cooling the substrate holder to a first temperature between-150° C. and −40° C.;
while maintaining the first temperature of the substrate holder, stabilizing the substrate at a second temperature over a second time period; and
after the second time period, exposing the substrate to a plasma over a third time period, the plasma being generated from a gas mixture comprising an etching gas and a passivating gas, the etching gas comprising oxygen, the passivating gas comprising silicon and fluorine.

16. The method of claim 15, wherein the gas mixture further comprises a sulfur-containing gas.

17. The method of claim 15, wherein cooling the substrate holder comprises a constant rate of cooling, the first time period lasting between 10 minutes and 30 minutes.

18. The method of claim 15, wherein cooling the substrate holder comprises stages, each stage comprising a constant rate of cooling and a duration, a sum of the durations of the stages equaling the first time period.

19. The method of claim 15, wherein stabilizing the substrate comprises cooling the substrate through physical contact with the substrate holder for a second time period lasting between 15 seconds and 2 minutes.

20. The method of claim 15, wherein selecting a third time period lasting at least 5 minutes forms a channel in the carbon-containing layer comprising an aspect ratio of at least 20:1.
